(19) United States
(12) Patent Application Publication
(10) Pub. No.: US 2008/0224268 A1
(43) Pub. Date: Sep. 18, 2008

(54) NITRIDE SEMICONDUCTOR SINGLE CRYSTAL SUBSTRATE

(75) Inventors: Yoshihisa Abe, Hadano City (JP); Jun Komiyama, Hadano City (JP); Shunichi Suzuki, Hadano City (JP); Akira Yoshida, Hadano City (JP); Hideo Nakanishi, Hadano City (JP)

Correspondence Address: FOLEY AND LARDNER LLP;SUITE 500, 3000 K STREET NW, WASHINGTON, DC, 20007, US

(73) Assignee: COVALENT MATERIALS CORPORATION

(21) Appl. No.: 12/040,020

(22) Filed: Feb. 29, 2008

(30) Foreign Application Priority Data
Mar. 13, 2007 (JP) 2007-062896
Sep. 14, 2007 (JP) 2007-239008

(51) Int. Cl. H01L 29/20

(52) U.S. Cl. 257/615; 257/E29.089

(57) ABSTRACT

To provide a nitride semiconductor single crystal substrate comprising a Si substrate and a nitride semiconductor film which has semi-polar (10-1m) plane (m: natural number) and a thickness of 1 μm or more, the nitride semiconductor single crystal substrate being suitably used for a light-emitting device, the nitride semiconductor single crystal substrate being suitably used for a light-emitting device, this invention provides a nitride semiconductor single crystal substrate comprising a Si substrate having an off-cut angle of 1 to 35° in the <110> direction from the <100> direction, a buffer layer 2a (2b) made of at least one of SiC or BP formed on the Si substrate, a AlN buffer layer formed on the buffer layers, and a nitride semiconductor single crystal film formed on the AlN buffer layer, the nitride semiconductor single crystal film comprising any one of GaN (10-1m), AlN (10-1m), InN (10-1m) or a GaN (10-1m)/and AlN (10-1m) superlattice film.

### BACKGROUND OF THE INVENTION

1. Field of the Invention

The present invention relates to a nitride semiconductor single crystal made of gallium nitride (GaN), aluminum nitride (AlN) and the like to be used suitably for light-emitting diodes, laser light-emitting diodes, high-speed and high-temperature operable electronic elements.

2. Description of the Related Art

Nitride semiconductors typified by GaN and AlN have a wide band gap and are materials expected to be applied to light-emitting diodes, laser light-emitting elements or high-speed and high-temperature operable electronic elements or the like as compound semiconductors having excellent characteristics such as high electron mobility and high heat resistance.

Because the above nitride semiconductors have a high melting point and the equilibrium vapor pressure of nitrogen is very high, the growth of a bulk crystal from a molten solution is not easy. For this reason, a single crystal of the nitride semiconductor is manufactured by hetero epitaxial crystal growth on a dissimilar substrate.

When a substrate of sapphire (0001), 6H—SiC (0001), Si (111) or the like is used, a GaN (0001) or AlN (0001) single crystal film has been formed by using a buffer layer interposed between the substrates and the single crystal films so far.

Among these substrates, a Si substrate has higher crystallinity, is obtained as a substrate having a wider area and is obtained at lower cost than other substrates, and can reduce the production cost of a nitride semiconductor, and has been therefore regarded as a suitable material.

Also, the formation of a nitride semiconductor film, a Si substrate being used, allows a successive use of the current silicon technologies and is therefore desired to be put to practical use also from the viewpoint of the superiority as to the developing cost of industrial technologies.

However, when a nitride semiconductor single crystal film is formed, a Si substrate being used, the nitride semiconductor single crystal film is broken because of a difference in thermal expansion coefficient between Si and a nitride semiconductor, and also, many crystal defects are caused by a difference in crystal lattice constant between Si and a nitride semiconductor. Therefore, it is difficult to form a nitride semiconductor single crystal film of 1 μm or more in thickness.

This is the reason why in the case of forming a nitride semiconductor single crystal film on a Si substrate, the nitride semiconductor single crystal film must be formed via an appropriate buffer layer.

As to such a buffer layer, it is known that in the case of forming, for example, 3C—SiC (111) layer on a Si (110) substrate, the lattice mismatching between Si and 3C—SiC is more relaxative than in the case of using a Si (111) substrate and the crystallinity of 3C—SiC (111) layer is improved (see, for example, Japanese Patent Application Laid-Open No. 2005-223206).

Also, it has been proposed to adopt a GaN/AlN superlattice film, and a 3C—SiC (111) layer as a buffer layer.

Also, Applied Physics Letters, vol. 84, No. 23, Jul. 7, 2004, p. 4747 to p. 4749 discloses that when GaN (10-12) is formed, a Si (001) substrate being used, it exhibits orientating characteristics when the off-cut angle of the Si substrate is designed to be 2 to 6°.

However, when a nitride semiconductor is utilized as a light-emitting device, the above nitride semiconductor single crystal film having the (0001) plane has the problem that the recombination of electrons and holes is inhibited by the spontaneous polarization of the crystal, leading to a reduction in luminous efficacy even if a substrate and a buffer layer such as those mentioned above are adopted.

Also, GaN (10-12) described in the above Applied Physics Letters, vol. 84, No. 23, Jul. 7, 2004, p. 4747-p. 4749 is not formed on a buffer layer and is not said to be a satisfactory one having good orientating characteristics.

It is therefore desired, in terms of improvement in luminous efficacy, to use the (10-10) and (11-20) planes which are non-polar crystal planes or the (10-1m) and (11-2n) planes which are semi-polar planes (here, m: natural numbers and n: natural numbers of 2 or more; the same as follows) as a nitride semiconductor single crystal film suited for a light-emitting device.

In view of this situation, the inventors of the present invention have focused on the utilization of a 3C—SiC or BP buffer layer formed on a substrate manufactured by processing Si (100) by off-cut treatment when a nitride semiconductor crystal film such as GaN (10-1m) or AlN (10-1m) is formed and found that the above nitride semiconductor crystal film can be formed in a thickness of 1 μm or more.

### SUMMARY OF THE INVENTION

In view of the above situation, the present invention has been made to solve the above technical problems and it is an object of the present invention to provide a nitride semiconductor single crystal substrate comprising a Si substrate and a nitride semiconductor film which has semi-polar (10-1m) plane (m: natural number) and a thickness of 1 μm or more, the nitride semiconductor single crystal substrate being suitably used for a light-emitting device.

A nitride semiconductor single crystal substrate according to the present invention comprises a Si substrate having an off-cut angle of 1 to 35° in the <110> direction from the <100> direction, a buffer layer made of at least one of SiC or BP formed on the Si substrate, a AlN buffer layer formed on the buffer layer made of SiC or BP, and a nitride semiconductor single crystal film formed on the AlN buffer layer, the nitride semiconductor single crystal film comprising any one of GaN (10-1m), AlN (10-1m) or InN (10-1m) (m: natural number).

The above structure enables the formation of a (10-1m) nitride semiconductor single crystal film having a thickness of 1 μm or more and excellent crystallinity, on the Si substrate.

A nitride semiconductor single crystal substrate in another embodiment according to the present invention comprises a Si substrate having an off-cut angle of 1 to 35° in the <110> direction from the <100> direction, a buffer layer made of at least one of SiC or BP formed on the Si substrate, a AlN buffer layer formed on the buffer layer made of SiC or BP, and a nitride semiconductor single crystal film formed on the AlN buffer layer, the nitride semiconductor single crystal film comprising a GaN/AlN superlattice film.

The formation of the superlattice structure of GaN and AlN as mentioned above makes it possible to more improve the crystallinity of the nitride semiconductor single crystal film.

The off-cut angle of the above Si substrate is preferably 7 to 9°.

As mentioned above, the present invention ensures that a GaN, AlN or InN single crystal film of 1 μm or more in thickness which has the (10-1m) plane which is a semi-polar crystal plane and is superior in crystallinity can be formed, a Si substrate being used.

Moreover, the formation of the GaN and AlN superlattice structure more improves the crystallinity of the nitride semiconductor single crystal film.

Therefore, the nitride semiconductor single crystal substrate maybe used suitably for light-emitting diodes, laser light-emitting devices and high-speed, high-temperature operable electronic devices and the like and particularly suitably for light-emitting devices. Therefore, the nitride semiconductor single crystal substrate can improve the functions of these devices.

### BRIEF DESCRIPTION OF THE DRAWINGS

FIG. 1 is a schematic sectional view showing an example of a layer structure of a nitride semiconductor single crystal substrate according to the present invention;

FIG. 2 is a schematic sectional view showing an example of a layer structure of a nitride semiconductor single crystal substrate according to the present invention;

FIG. 3 is a schematic sectional view showing an example of a layer structure of a nitride semiconductor single crystal substrate according to the present invention; and

FIG. 4 is a schematic sectional view showing an example of a layer structure of a nitride semiconductor single crystal substrate according to the present invention.

### DESCRIPTION OF THE PREFERRED EMBODIMENTS

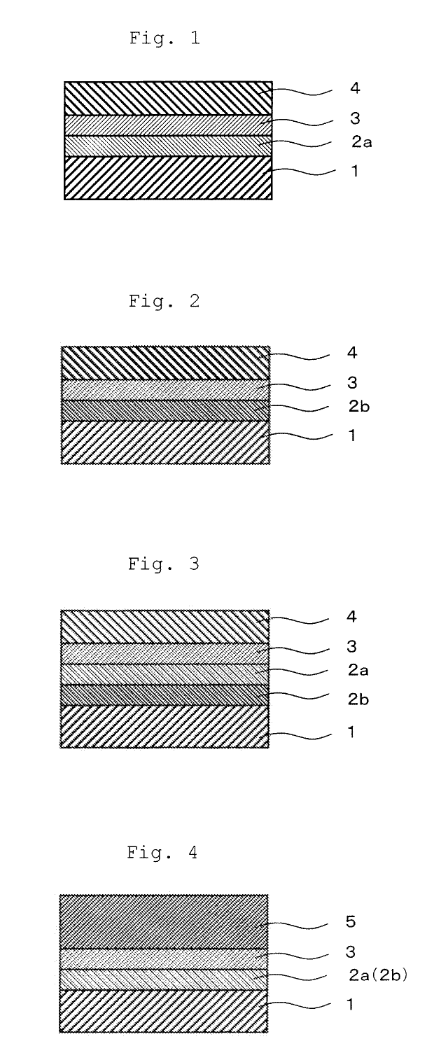

The present invention will be explained in more detail with reference to the drawings FIGS. 1 to 3 each show a schematic view of a layer structure of a nitride semiconductor single crystal substrate according to the present invention.

The nitride semiconductor single crystal substrate shown in FIG. 1 comprises a Si crystal substrate 1, a SiC buffer layer 2a formed on the Si crystal substrate 1, an AlN buffer layer 3 formed on the a SiC buffer layer 2a, and a GaN, AlN or InN single crystal film 4 formed on the an AlN buffer layer 3.

Also, the nitride semiconductor single crystal substrate shown in FIG. 2 has the same structure as that shown in FIG. 1 except that a BP buffer layer 2b is formed instead of the SiC buffer layer 2a.

Also, the nitride semiconductor single crystal substrate shown in FIG. 3 has the same structure as that shown in FIG. 1 except that a BP buffer layer 2b is formed between the Si crystal substrate and the SiC buffer layer 2a.

The nitride semiconductor single crystals films are obtained as a single crystal having the (10-1m) plane and excellent crystallinity when a substrate made of Si (100) off-cut at an angle of 1 to 35° in the <110> direction from the <100> direction is used and a buffer layer made of one or both of 3C—SiC and BP is formed on the substrate.

Also, since the nitride semiconductor single crystal film having the (10-1m) plane is formed, a Si substrate being used, the equipment and technologies that have been used so far in conventional Si semiconductor production processes can be utilized and therefore, the nitride semiconductor single crystal film has the advantage that it can be obtained as one having a large diameter at low costs.

The Si single crystal substrate used in the present invention is not particularly limited in its production method. The Si single crystal substrate may be produced by the Czochralski (CZ) method or floating zone (FZ) method. Also, this substrate may be one (Si epitaxial substrate) obtained by the epitaxial growth of a Si single crystal layer on a Si single crystal substrate according to a vapor phase growth method.

The off-cut angle of the above Si substrate is preferably 1 to 35° in the <110> direction from the <100> direction.

When the above off-cut angle is less than 1°, a nitride grown through the SiC or BP buffer layer is not oriented on a non-polar plane but is (0001)-oriented.

When the above off-cut angle exceeds 35° on the other hand, the aforementioned Si (100) is almost Si (111) and the nitride grown through the SiC or BP buffer layer is (0001)-oriented.

The off-cut angle of the above Si substrate is preferably 8°±1.0°, that is 7 to 9°.

Although the off-cut angle is more preferably 8°, the allowable range of ±1.0° is defined taking processing preciseness into account.

The use of such a Si substrate can limit the breakage and crystal defects of the nitride semiconductor single crystal film on the entire surface, whereby a (10-1m) nitride semiconductor single crystal film being superior in crystallinity can be obtained in a thickness of 1 μm or more.

It is to be noted that when the off-cut angle is in the above range, m=2.

The above off-cut substrate of Si (100) is preferably preliminarily purified by removing the native oxide film on the surface by cleaning it using hydrogen gas before the buffer layer made of one or both of SiC and BP is formed thereon.

Moreover, the above Si substrate is preferably preliminarily heat-treated using hydrocarbon type gas such as propane at 1000 to 1350° C. to thereby carbonize the surface thereof.

If such carbonation treatment is performed in advance, this can prevent Si from being dissociated from the surface of the Si substrate when the SiC buffer layer is formed.

The buffer layer made of one or more of SiC and BP and formed on the off-cut substrate of Si (100) may be formed only of the SiC layer 2 as shown in FIG. 1 or only of the BP layer 2b as shown in FIG. 2, or may be formed of both the SiC layer 2a and the BP layer 2b as shown in FIG. 3.

When both SiC and BP are selected in the above buffer layer, it is preferable to form the SiC layer 2a on the formed BP layer 2b as shown in FIG. 3.

Because BP has a lattice constant between the lattice constants of Si and SiC, the BP layer is interposed between the off-cut substrate of Si (100) and the SiC layer, whereby the effect as the buffer layer can be improved and also, the SiC layer can be efficiently formed as a film reduced in the density of defects.

Also, the AlN buffer layer 3 is formed on the above SiC or BP buffer layer.

This AlN buffer layer 3 serves to restrain the crystal lattice mismatching between the SiC 2a or BP buffer layer 2b formed on the substrate 1 and GaN, AlN or InN single crystal film 4.

The thickness of the above AlN buffer layer is preferably as low as possible from the viewpoint of production cost. However, this AlN buffer layer is formed in such a thickness enough to obtain the effect of restraining the above crystal lattice mismatching between the SiC or BP buffer layer formed on the substrate and GaN (10-1m), AlN (10-1m) or InN (10-1m) single crystal film. Specifically, the thickness of the AlN buffer layer is preferably of the order of 1 to 500 nm.

The above AlN buffer layer may be formed on the above SiC or BP buffer layer by epitaxial growth according to, for example, a vapor phase growth method.

Then, a GaN (10-1m), AlN (10-1m) or InN (10-1m) single crystal film is formed on the AlN buffer layer by epitaxial growth, whereby the nitride semiconductor single crystal films can be respectively formed as a film having a thickness of 1 μm or more and excellent crystallinity.

Moreover, FIG. 4 shows a further aspect of a layer structure of the nitride semiconductor single crystal substrate according to the present invention.

When, as shown in FIG. 4, the nitride semiconductor single crystal film is constituted of a superlattice film 5 in which a GaN (10-1m) and AlN (10-1m) are alternately laminated as thin films on the AlN buffer layer 3 which is formed on the SiC or BP buffer later 2a (2b) in the same manner as that shown in any of FIGS. 1 to 3, thereby making it possible to more improve the crystallinity of the nitride semiconductor single crystal films.

### EXAMPLES

The present invention will be explained in more detail by way of examples, which, however, are not intended to be limiting of the present invention.

### Example 1

A Si substrate made of Si (100) off-cut at an angle of 8° in the <110> direction from the <100> direction was set to the growth zone in a reaction tube and the above Si substrate was heated to 1100° C. with supplying hydrogen as a carrier gas to carry out cleaning of the surface of the substrate.

Then, propane was supplied and the temperature of the substrate was set to 1000 to 1350° C. to carbonize the surface of the Si substrate. Then, propane and silane were supplied to form a SiC buffer layer of 10 to 10000 nm in thickness.

Next, trimethylalminium (TMA) and ammonia were supplied as raw materials while keeping the temperature of the substrate to form an AlN buffer layer of 1 to 500 nm in thickness on the above SiC layer.

Moreover, the temperature of the substrate was dropped to about 1000° C. and trimethylgallium (TMG) and ammonia were supplied as raw materials to form a GaN single crystal film on the above AlN buffer layer.

Even when the above GaN single crystal film was formed in a thickness of 1 μm or more, a flat surface was obtained without any cracks found thereon. Also, the azimuth of the orientation was <10-12>.

### Example 2

A SiC buffer layer and an AlN buffer layer were formed on a Si substrate made of Si (100) off-cut at an angle of 8° in the <110> direction from the <100> direction in the same manner as in Example 1.

Next, the substrate was heated to 1200° C. or more and TMA and ammonia were supplied as raw materials to form an AlN single crystal film on the above AlN buffer layer.

Even when the above AlN single crystal film was formed in a thickness of 1 μm or more, a flat surface was obtained without any cracks found thereon. Also, the azimuth of the orientation was <10-12>.

### Example 3

A SiC buffer layer and an AlN buffer layer were formed on a Si substrate made of Si (100) off-cut at an angle of 8° in the <110> direction from the <100> direction in the same manner as in Example 1.

Next, the substrate was heated to 500° C. or more and trimethylindium (TMIn) and ammonia were supplied as raw materials to form an InN single crystal film on the above AlN buffer layer.

Even when the above InN single crystal film was formed in a thickness of 1 μm or more, a flat surface was obtained without any cracks found thereon. Also, the azimuth of the orientation was <10-12>.

### Example 4

PH₃ gas and B₂H₆ gas were supplied to a Si substrate cleaned in the same manner as in Example 1 to form a BP buffer layer of 10 to 500 nm in thickness.

An AlN buffer layer and a GaN single crystal film were formed on the BP buffer layer in the same manner as in Example 1.

Even when the above GaN single crystal film was formed in a thickness of 1 μm or more, a flat surface was obtained without any cracks found thereon. Also, the azimuth of the orientation was <10-12>.

### Example 5

A BP buffer layer and an AlN buffer layer were formed on a Si substrate made of Si (100) off-cut at an angle of 8° in the <110> direction from the <100> direction in the same manner as in Example 4.

An AlN single crystal film was formed on the AlN buffer layer in the same manner as in Example 2.

Even when the above AlN single crystal film was formed in a thickness of 1 μm or more, a flat surface was obtained without any cracks found thereon. Also, the azimuth of the orientation was <10-12>.

### Example 6

A BP buffer layer and an AlN buffer layer were formed on a Si substrate made of Si (100) off-cut at an angle of 8° in the <110> direction from the <100> direction in the same manner as in Example 4.

An InN single crystal film was formed on the AlN buffer layer in the same manner as in Example 3.

Even when the above InN single crystal film was formed in a thickness of 1 μm or more, a flat surface was obtained without any cracks found thereon. Also, the azimuth of the orientation was <10-12>.

### Example 7

A SiC buffer layer and an AlN buffer layer were formed on a Si substrate made of Si (100) off-cut at an angle of 8° in the <110> direction from the <100> direction in the same manner as in Example 1.

Then, the temperature of the substrate was dropped to about 1000° C. and TMG and ammonia were supplied as raw materials to form a GaN single crystal film of 1 to 500 nm in thickness on the AlN buffer layer. Further, TMA and ammonia were supplied as raw materials while keeping the temperature of the substrate to form an AlN single crystal film of 1 to 500 nm in thickness on the above GaN single crystal film. The GaN single crystal film and the AlN single crystal film were repeatedly alternately laminated on each other in the same manner as above to form a superlattice film.

Even when the above superlattice film was formed in a thickness of 1 μm or more, a flat surface was obtained without any cracks found thereon. Also, the azimuth of the orientation was <10-12>.

### Example 8

A SiC buffer layer, an AlN buffer layer and a GaN single crystal film were formed on a Si substrate made of Si (100) off-cut at an angle of 4° in the <110> direction from the <100> direction in the same manner as in Example 1.

In the above GaN single crystal film, a flat surface was not obtained in a part of the GaN single crystal film. However, no crack was found in other parts and the azimuth of the orientation was <10-12>.

### Comparative Examples 1 and 2

A SiC buffer layer, an AlN buffer layer and a GaN single crystal film were formed on a Si substrate made of Si (100) off-cut at an angle of 0° (Comparative Example 1) or 45° (Comparative Example 2) in the <110> direction from the <100> direction in the same manner as in Example 1.

In the above GaN single crystal film, a flat surface was not obtained on the entire surface.

What is claimed is:

1. A nitride semiconductor single crystal substrate comprising;
a Si substrate having an off-cut angle of 1 to 35° in the <110> direction from the <100> direction,
a buffer layer made of SiC or BP formed on the Si substrate,
a AlN buffer layer formed on the buffer layer made of SiC or BP, and
a nitride semiconductor single crystal film formed on the AlN buffer layer, the nitride semiconductor single crystal film comprising any one of GaN (10-1m), AlN (10-1m) or InN (10-1m) (m: natural number).

2. A nitride semiconductor single crystal substrate comprising;
a Si substrate having an off-cut angle of 1 to 35° in the <110> direction from the <100> direction,
a BP buffer layer formed on the Si substrate,
a 3C—SiC buffer layer formed on the BP buffer layer,
a AlN buffer layer formed on the 3C—SiC buffer layer, and
a nitride semiconductor single crystal film formed on the AlN buffer layer, the nitride semiconductor single crystal film comprising anyone of GaN (10-1m), AlN (10-1m) or InN (10-1m) (m: natural number).

3. A nitride semiconductor single crystal substrate comprising;
a Si substrate having an off-cut angle of 1 to 35° in the <110> direction from the (100) direction,
a buffer layer made of SiC or BP formed on the Si substrate,
a AlN buffer layer formed on the buffer layer made of SiC or BP, and
a nitride semiconductor single crystal film formed on the AlN buffer layer, the nitride semiconductor single crystal film comprising a GaN/AlN superlattice film.

4. A nitride semiconductor single crystal substrate comprising;
a Si substrate having an off-cut angle of 1 to 35° in the <110> direction from the <100> direction,
a BP buffer layer formed on the Si substrate,
a 3C—SiC buffer layer formed on the BP buffer layer,
a AlN buffer layer formed on the 3C—SiC buffer layer, and
a nitride semiconductor single crystal film formed on the AlN buffer layer, the nitride semiconductor single crystal film comprising a GaN/AlN superlattice film.

5. The nitride semiconductor single crystal substrate according to claim 1, wherein the off-cut angle of the Si substrate is 7 to 9°.

6. The nitride semiconductor single crystal substrate according to claim 2, wherein the off-cut angle of the Si substrate is 7 to 9°.

7. The nitride semiconductor single crystal substrate according to claim 3, wherein the off-cut angle of the Si substrate is 7 to 9°.

8. The nitride semiconductor single crystal substrate according to claim 4, wherein the off-cut angle of the Si substrate is 7 to 9°.
